(19) United States
(12) Patent Application Publication
(10) Pub. No.: US 2006/0183325 A1
(43) Pub. Date: Aug. 17, 2006

(54) Lift-off method

(75) Inventors: Martin Franosch, Munich (DE); Klaus-Guenter Oppermann, Holzkirchen (DE)

Correspondence Address: Maginot, Moore & Beck;Chase Tower, Suite 3250, 111 Monument Circle, Indianapolis, IN, 46204, US

(73) Assignee: Infineon Technologies AG, Munchen (DE)

(21) Appl. No.: 11/331,434

(22) Filed: Jan. 12, 2006

(30) Foreign Application Priority Data
Jan. 19, 2005 (DE) 102005002550.1-33

(51) Int. Cl. H01L 21/44

(52) U.S. Cl. 438/670

(57) ABSTRACT

A lift-off method includes providing a material structure, applying photoresist on a surface of the material structure, partially exposing the photoresist, baking the material structure with the partially exposed photoresist applied on the surface of the material structure, developing the photoresist with an organic, polar developer, so that the photoresist is removed in a first region of the surface, and the photoresist remains in the second region of the surface, applying coating material on the surface of the material structure and the remaining photoresist, and removing the photoresist.

### CROSS-REFERENCE TO RELATED APPLICATION

This application claims priority from German Patent Application No. 102005002550.1, which was filed on Jan. 19, 2005, and is incorporated herein by reference in its entirety.

### BACKGROUND OF THE INVENTION

1. Field of the Invention

The present invention relates to a lift-off method.

2. Description of the Related Art

For structuring hard-to-etch substances, such as gold, lift-off methods or methods for structured application of a coating material on a material structure are employed in semiconductor technology, for example when processing wafers. In this, photoresist, such as negative resist, is applied on a material structure, such as a multi-layer construction, a substrate, or a wafer, and then at least partly exposed. After exposing the photoresist, baking the material structure, on which the photoresist has been applied, frequently takes place. In baking, the cross-linkage of the negative resist is strengthened. In this, for example, baking cures negative resist, for example, more strongly in the exposed regions. After baking, the negative resist is developed, so that the exposed or more strongly cross-linked regions remain on the material structure, whereas the non-exposed or less strongly cross-linked regions of the photoresist are dissolved out or removed by the developer, so that a material structure with a structured photoresist layer applied on the material structure develops.

Then, coating material is applied on the material structure on the structured negative resist layer in full-area manner. The coating material is directly applied on the material structure in the regions in which the photoresist has been removed from the material structure. In the regions in which the photoresist has not been removed, the coating material is applied on the negative resist layer. Finally, the negative resist is removed, and the coating material layer applied thereon along with it. In the regions in which the photoresist has not been removed during exposing, the material structure is thus not coated by the coating material. Positive resist may also be used in the lift-off method. In this, the exposed regions are dissolved out or removed by the developer.

For developing the negative resist, an aqueous solution of the material TMAH or tetra-methyl-ammonium-hydroxide has previously been employed. This solution is highly alkaline, with the pH ranging from 13.5 to 14, so that corrosion may occur in the solution during the developing process when contacting metal on the material structure by the developer. This corrosion increasingly occurs, when a stack of different metals is in direct contact to each other and at the same time has contact with the developer because of the procedural sequence.

The material structure is often embodied as a wafer in industrial fabrication processes. After exposing, the wafers are often heated over a period of 60 seconds at an ambient temperature of 105°, which is referred to as baking or PEB or post-exposure baking in the literature. Then the negative resist is developed in an aqueous developer, which often comprises an aqueous solution having 2.38% of TMAH. The aqueous solution has a pH of 13.5, which leads to a strong corrosive attack on all metals coming into direct contact with the developer. In this, microscopically small inclusions of foreign metals, such as of copper in aluminum, which may only have the size of several nanometers, may already form a corrosion element, which leads to the dissolution of the less noble metal. If several metals, such as titanium, platinum, tungsten, molybdenum, gold, aluminum, or an aluminum-copper alloy, are in a multi-layer construction or a layer stack on the wafer and in direct contact with the aqueous solvent during developing the photoresist, corrosion results.

More specifically, when two different metals in the multi-layer construction come into direct contact with the aqueous developer, corrosion of the respective less noble metal develops in the multi-layer construction. The fact of which of the metals is the less noble metal in the multi-layer construction is determined by the position in the electrochemical series. The reaction rate at which the less noble metal corrodes substantially depends on the distance of the two metals in the electrochemical series, the concentration of the OH⁻ ions or the pH of the developer, the temperature and mobility of the OH⁻ ions.

One consequence of the corrosion is an attack on the contact pads applied on the wafer, for example. As a result of the corrosion, these have diminished bondability. In particular, a gold layer vapor deposited on the contact pads attacked by the corrosion exhibits a very rough surface visible as a dark area in an optical inspection in a microscope. This dark area is an indicator for the rough surface of the gold pads and for the fact that the gold pads are no longer bondable and often also not suited as under-bump metallization.

The destruction of the contact pads by the corrosion leads to reduced fabrication yield. The silicon dies arranged on a wafer, the contact pads of which are destroyed as a result of the corrosion, can no longer be bonded and are therefore not suited for employment in a semiconductor device. They are therefore discarded after dicing the semiconductor dies of the wafer.

The corrosion of contact pads on the wafer is especially disadvantageous in the production of bulk acoustic wave resonators or bulk acoustic wave filters or BAW filters employed in mobile telephones. Here, the contact pads comprise a stack of several metals. This stack is contacted with a conducting measurement tip in a measurement of the frequency, which is preferably performed on wafer level in industrial fabrication methods. In this, the contact pads are connected to the conducting measurement tip of a tester, which then checks the frequency response of the BAW filters. The contact with the measurement tip or the needle often leads to the needle piercing metal layers in the contact pad and the metals in the contacting region blending with each other. The metals blended with each other form a multiplicity of corrosion elements, wherein the less noble metal in the contact pads is dissolved during the ensuing development process, i.e. developing the negative resist.

This may in turn lead to a great number of the contact pads of the semiconductor dies arranged on the wafer being unsuitable for bonding. This in turn leads to correspondingly high yield losses. In this, it is especially critical that, in some applications of the BAW filters, it is demanded of these that all BAW filters located on a wafer have already been tested on wafer level and therefore have been contacted with a measurement tip.

The only possibility previously known of protecting a contact pad on the wafer from corrosion is to coat this with a cover of silicon nitride or silicon oxide prior to developing. But this would require a further procedural step in the lift-off method in the industrial fabrication and would thus render the industrial fabrication process more intensive.

### SUMMARY OF THE INVENTION

It is an object of the present invention to provide an improved lift-off method enabling production with higher yield.

In accordance with a first aspect, the present invention provides a lift-off method, having the steps of: providing a material structure; applying photoresist on a surface of the material structure; partially exposing the photoresist; baking the material structure with the partially exposed photoresist applied on the surface of the material structure; developing the photoresist with an organic, polar developer, so that the photoresist is removed in a first region of the surface, and the photoresist remains in a second region of the surface; applying coating material on the surface of the material structure and the remaining photoresist; and removing the photoresist, so that the coating material remains only in the first region.

An inventive lift-off method includes providing a material structure, applying photoresist on a surface of the material structure, partially exposing the photoresist, baking the material structure with the partially exposed photoresist applied on the surface of the material structure, developing the photoresist with an organic, polar solvent or developer, so that the photoresist is removed in a first region of the surface and the photoresist remains in a second region of the surface, applying coating material on the surface of the material structure and the remaining photoresist, and removing the photoresist.

The present invention is based on the finding that photoresist, which has been applied on a surface of a material structure, can be developed with an organic, polar solvent in a lift-off method. The organic, polar solvent has no corrosive effect in contrast to the solvent employed in the conventional lift-off method. The corrosive effect on a multi-layer construction of several metals, such as a contact pad, arranged on the material structure is thus prevented or reduced as opposed to the conventional lift-off method.

The prevention of the corrosive effect of the developer on the contact pads leads to the fact that the contact pads are better bondable on a wafer processed with a lift-off method according to an embodiment of the present invention, than the contact pads on a wafer processed according to the conventional lift-off method. The prevention of the corrosive action of the lift-off method leads to a smoother surface of the contact pads, which entails the better bondability.

At the same time, in industrial mass production, the proportion of the useful semiconductor dies on a wafer processed by means of a lift-off method according to an embodiment of the present invention is higher. A greater proportion of the contact pads has suitable bondability than in a wafer processed by means of the conventional lift-off method. Thus, in the industrial mass production, the yield is increased by the employment of a lift-off method according to an embodiment of the present invention as opposed to the conventional lift-off method. At the same time, the fabrication costs may be lowered by the application of the lift-off method according to an embodiment of the present invention as opposed to a fabrication method employing the conventional lift-off method.

The prevention of the corrosive action on the contact pads in a lift-off method according to an embodiment of the present invention at the same time enables greater ease of fabrication. In the conventional lift-off method, the contact pads are to be protected, if applicable, from the corrosive effect of the solvent by coating with a silicon nitride or silicon oxide layer. By the prevention of the corrosive action of the lift-off method according to an embodiment of the present invention, coating the contact pads with a silicon nitride or silicon oxide layer is not required.

Although the organic, polar solvent exhibits no corrosive effect, the effect of the organic, polar solvent for selectively removing the photoresist is also reduced as opposed to the conventional method. Hence, in the employment of the polar solvent for selectively removing the photoresist, stronger baking is required. According to an embodiment of the present invention, the stronger baking is performed over a period ranging from 300 seconds to 1,500 seconds, and preferably over a period ranging from 500 seconds to 600 seconds, and a temperature ranging from 110° C. to 150° C. According to embodiments of the present invention, these ranges are chosen so that the non-cross-linked resist is removed when developing on the one hand, whereas the cross-linked resist is sufficiently hard in order to still remain on the material structure after developing, and the cross-linked resist is not too hard, on the other hand, so that it can then still be removed in a following procedural step by another, such as a stronger, solvent.

### BRIEF DESCRIPTION OF THE DRAWINGS

These and other objects and features of the present invention will become clear from the following description taken in conjunction with the accompanying drawings, in which:

FIG. 1 shows a lift-off method according to an embodiment of the present invention;

FIGS. 2a-e are schematic views of a material structure processed with a lift-off method according to an embodiment of the present invention;

FIG. 3a is an excerpt of a surface of a wafer processed with a conventional lift-off method;

FIG. 3b is an excerpt of a surface of a wafer processed with a lift-off method according to an embodiment of the present invention;

FIG. 4 is a comparison of the resist thicknesses and trench widths on a wafer processed by means of a conventional lift-off method as opposed to a wafer processed with a lift-off method according to an embodiment of the present invention;

FIGS. 5a-b are a comparison of trenches in a photoresist on a wafer, which have been created according to a conventional lift-off method and a lift-off method according to an embodiment of the present invention;

FIG. 6a shows an edge of a photoresist in a conventional lift-off method; and

FIG. 6b shows an edge of a photoresist structured in a lift-off method according to an embodiment of the present invention.

### DESCRIPTION OF THE PREFERRED EMBODIMENTS

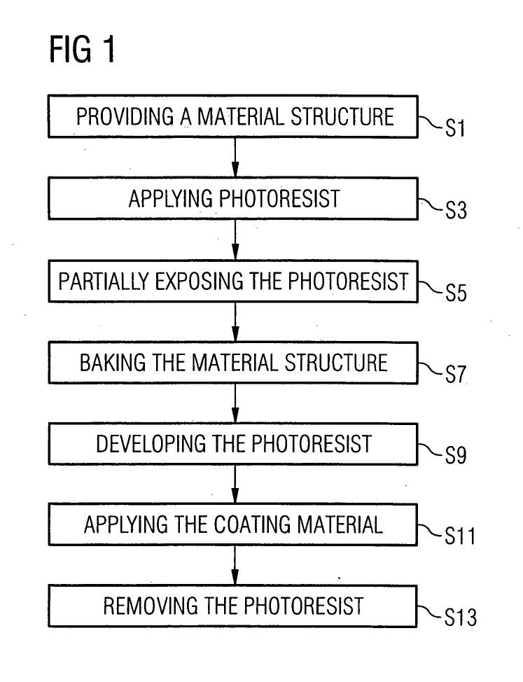

FIG. 1 explains a course of a lift-off method according to an embodiment of the present invention. In a step S1, a material structure, such as a wafer with contact pads, is provided. In a following step S3, a negative resist is applied on a surface of the material structure. Then, in a step S5, the surface on which the negative resist is applied is partially exposed, so that the regions of the negative resist, which are supposed to remain on the surface in the ensuing developing of the photoresist, and on which the coating material applied on the material structure with the lift-off method is not to be present later, are irradiated with light.

Thereafter, in a step S7, baking the material structure, on which the negative resist has been applied on a surface thereof, is performed. Here, the material structure is baked, for example, in an oven at a temperature of 120° C. over a period of 600 seconds. Baking the material structure leads to increased cross-linkage of the negative resist or to curing the negative resist. The aim of baking is to increase the cross-linkage of the negative resist in the exposed region so that the negative resist is not dissolved out in ensuing developing.

After that, in a step S9, the negative resist is developed with a developer. As developer, a 2-propanol solvent and/or PGMEA is used, which is arranged on the surface on which the photoresist has been applied. The 2-propanol solvent now selectively dissolves out the negative resist in the regions of the photoresist not exposed in step S5, while the exposed and thus cross-linked regions remain. Thus, only the regions of the negative resist exposed in step S5 remain on the surface of the material structure.

Then, in a step S11, coating material, such as gold, titanium, or platinum is vapor-deposited on the surface of the material structure on which the negative resist has originally been applied. Thus, a layer of the coating material then covers the material structure at the locations at which the photoresist has been removed when developing S9, while at the same time the remaining photoresist regions are also coated by a coating material layer.

In a subsequent step S13, the negative resist is removed from the surface of the material structure, wherein the coating material vapor-deposited thereon is also removed therewith. Removing the photoresist takes place by applying or bringing into contact a strong solvent, such as n-methyl-pyrrolidone, with the material structure, such as dipping the material structure into a basin filled with n-methyl-pyrrolidone.

Due to the absence of movable ions, developing the photoresist by means of the 2-propanol solvent does not lead to metals on the surface of the material structure being destroyed by corrosion. The 2-propanol solvent has the property that it indeed removes the negative resist from the exposed regions on the one hand, and thus structures the negative resist, but does not attack a contact pad embodied out of several metals by corrosion on the other hand. The reason for a contact pad not being attacked by the 2-propanol solvent lies in the fact that no OH⁻ ions form in the 2-propanol solvent, as opposed to in the conventional lift-off method.

The lift-off method illustrated in FIG. 1 is especially advantageous if the material structure includes a wafer on which a plurality of piezoelectric resonators or BAW filters are implemented. In these, as already explained previously, protection of the contact pads from a corrosive effect of the solvent employed for developing is of great importance.

In the following, the lift-off method set forth in FIG. 1 according to an embodiment of the present invention will be explained on the basis of the schematic views of a material structure being processed with the lift-off method according to the embodiment of the present invention.

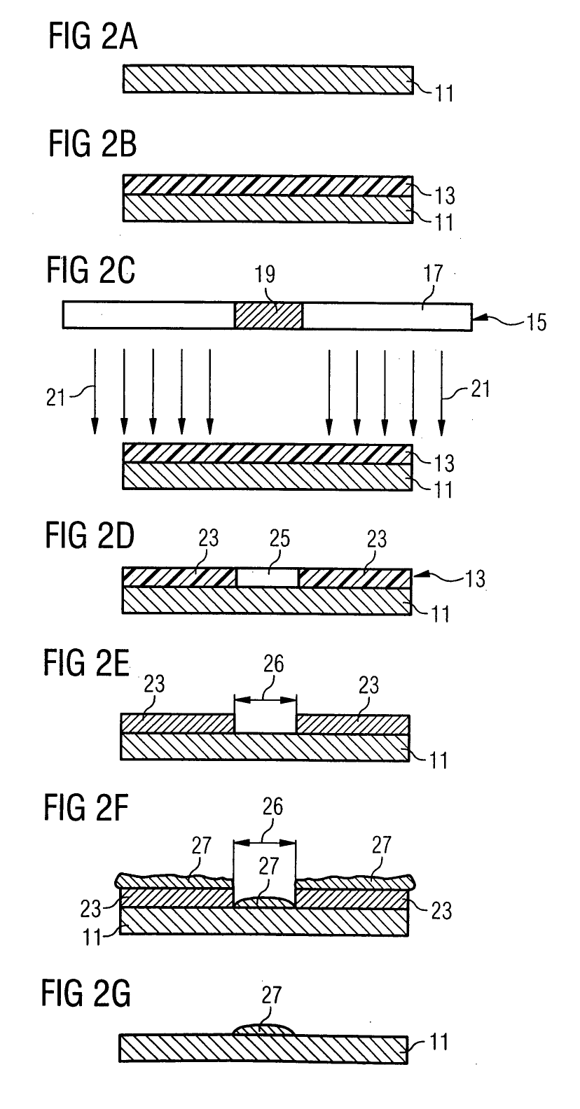

FIG. 2a shows the material structure 11 processed with the lift-off method according to the embodiments of the present invention. A contact pad not shown here is attached on a surface of the material structure.

FIG. 2b shows the material structure 11 after a negative resist 13, as described in FIG. 1 in step S3, has been applied on a surface of the material structure 11.

FIG. 2c shows an arrangement with which the negative resist 13 is being exposed. The exposing has already been mentioned in FIG. 1 in step S5. For this, a mask 15 is employed, which has a translucent region 17 and an opaque region 19. A light source (not shown here) is arranged on a side of the mask 15 facing away from the substrate 11. Light beams 21 generated thereby impinge on the mask 15 and are transmitted in the translucent region 17, whereas they cannot pass the mask 15 in the opaque region 19. The light beams 21 then impinge on the negative resist 13 after passing the mask 15, with regions exposed by the light beams 21 and regions not exposed by the light beams 21 forming in the negative resist 13.

FIG. 2d explains a construction of the substrate 11 with the negative resist 13 after exposure. The negative resist 13 now comprises exposed regions 23, which are illustrated in hatched manner here. Moreover, a non-exposed region 25 is present in the negative resist 13.

The arrangement shown in FIG. 2d is then inserted into an oven in order to increase the cross-linkage of the negative resist 13 in the exposed region 23 of the negative resist 13. In the oven, baking is performed, as already shown in step S7 in FIG. 1, with the duration for baking being about 600 seconds, for example, and there being an internal temperature of about 120° C., for example, in the oven.

Then, the arrangement shown in FIG. 2d is dipped into a basin filled with 2-propanol solvent, in order to bring the 2-propanol solvent into contact with the negative resist 13. In this, the negative resist 13 is removed from the non-exposed region 25 of the negative resist 13. In this, a trench, which has a trench width 26, develops between the exposed regions 23 of the negative resist 13.

This step is also referred to as developing and is illustrated in FIG. 1 as step S9 of developing the photoresist. The arrangement thus created is shown in FIG. 2e.

Thereafter, coating material 27 is vapor-deposited on the surface of the material structure 11 on which the negative resist 13 has been applied and on the exposed region 23 of the negative resist 13. This step is already mentioned in FIG. 1 as step S11 of applying the coating material 27. The arrangement thus created is shown in FIG. 2f. The material structure 11 and the exposed region 23 of the negative resist 13 are coated by the coating material 27. The material structure 11 is coated with the coating material 27 in the regions in which the negative resist 13 has not been exposed and has been removed in the step of developing.

Then the arrangement shown in FIG. 2f is brought into contact with a strong solvent, which is also capable of removing the negative resist 13 in the exposed regions 23. Hereby, the exposed regions 23 of the negative resist 13, and the coating material 27 arranged thereon along with it, are removed. This procedural step is already illustrated in FIG. 1 as step S13 of removing the photoresist. The arrangement thus created is shown in FIG. 2g.

It is especially advantageous in the lift-off method according to an embodiment of the present invention shown here that, for example, a contact pad not shown here on a surface of the material structure is not attacked by the 2-propanol solvent. The contact pad is thus not restricted in its bondability and still capable of making contact with a circuit structure arranged in the material structure 11 without restriction. As already explained previously, the reason is that the 2-propanol solvent creates no OH⁻¹ ions in developing, in contrast to the solvent employed in the conventional lift-off method. Thereby, the corrosion of the contact pad is prevented.

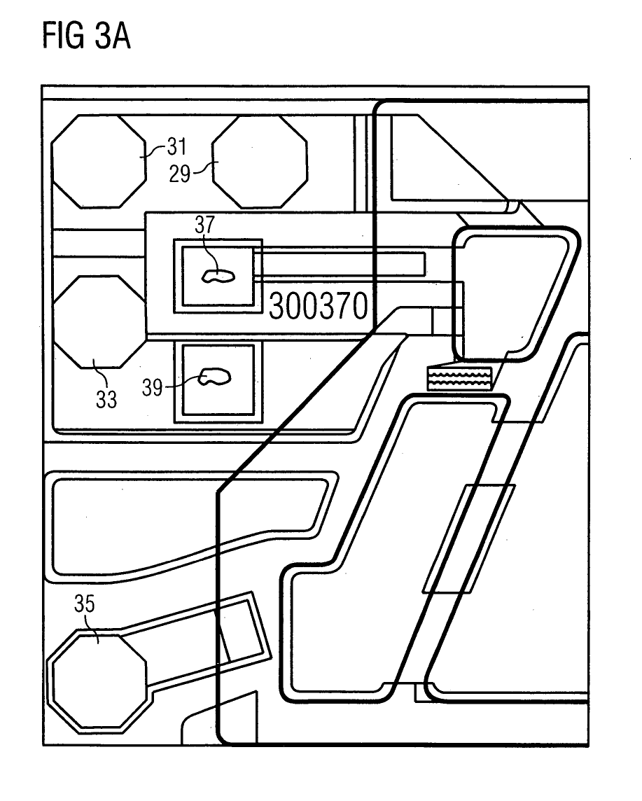

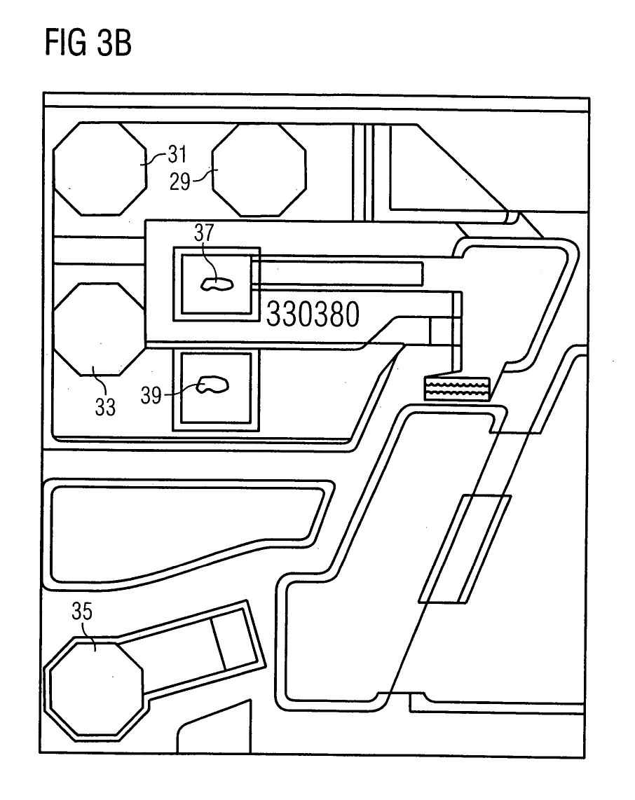

In the following, a wafer surface processed by means of a conventional lift-off method, as illustrated in FIG. 3a, and a wafer surface processed with a lift-off method according to an embodiment of the present invention are compared. In the comparison of the arrangement shown in the following, the same or equally acting elements are provided with the same reference numerals. The wafer surfaces are only illustrated in excerpts each.

FIG. 3a shows an excerpt of a wafer having been processed with the conventional lift-off method. On a surface of the wafer, a first pad 29, a second pad 31, a third pad 33, and a fourth pad 35, as well as a first measurement contact 37 and a second measurement contact 39 are arranged.

The first measurement contact 37 is connected to the first pad 29, the second pad 31, and the third pad 33 via electric traces not shown here in electrically conducting manner, whereas the second measurement contact 39 is connected to the fourth pad 35 in electrically conducting manner. In FIG. 3b, the same excerpt is shown for a wafer having been processed with a lift-off method according to an embodiment of the present invention. Comparison of the arrangements illustrated in FIG. 3a and FIG. 3b shows that the measurement contacts 37, 39 and the pads 29, 31, 33, 35 in FIG. 3a are clearly darker than in FIG. 3b. The darker the pads 29, 31, 33, 35 and the measurement contacts 37, 39 in the photographic images shown in FIGS. 3a and 3b, the rougher their surfaces.

The darker color of the pads 29, 31, 33, 35 and the measurement contacts 37, 39 in FIG. 3a results from the fact that, in the conventional lift-off method, the pads 29, 31, 33, 35 and the measurement contacts 37, 39 heavily corrode as a result of the solvent employed there, an aqueous solution with tetra-methyl-ammonium-hydroxide, with a great number of OH⁻ ions, whereas, in the lift-off method according to an embodiment of the present invention, the corrosion cannot take place. The darker color of the pads is an indication of the roughness of the surface, wherein, in the excerpt shown in FIG. 3a, the roughness of the surface of the pads 29, 31, 33, 35 is strongly increased as opposed to the pads 29, 31, 33, 35 illustrated in FIG. 3b.

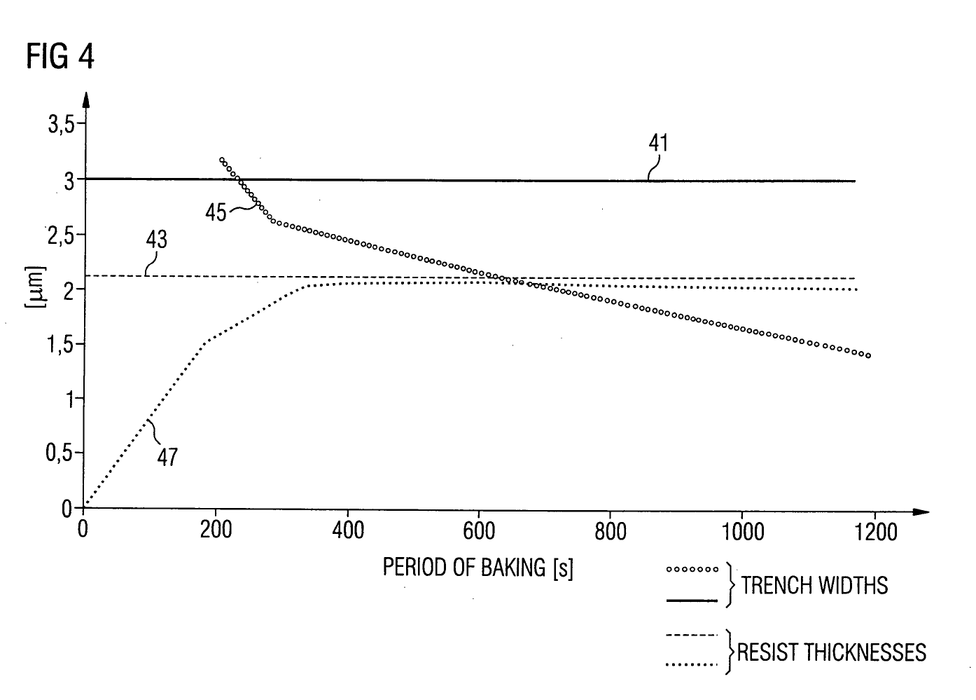

FIG. 4 explains a comparison of trench widths and resist thicknesses in the conventional lift-off method as opposed to the lift-off method according to an embodiment of the present invention. By a trench shown in FIGS. 2e-f, a trench-shaped recess in the negative resist after developing, which is arranged between two exposed regions of the negative resist not removed during developing, is meant.

A duration in seconds during which baking is performed is plotted along the x-axis, whereas the resist thickness and the trench width in μm are plotted along the y-axis. A horizontal line 41 shows a trench width in the conventional lift-off method, and a horizontal line 43 a resist thickness in the conventional lift-off method, as it has been described in the introductory section of the description. In the conventional lift-off method, baking is exemplarily performed over a period of 60s at a temperature of 105° C.

A curve shape 45 shown by a line of circle symbols represents a trench width in the lift-off method according to an embodiment of the present invention, as it results for various periods within which baking is performed. A curve shape 47 illustrated by a dotted line explains a course of the resist thickness in the lift-off method according to an embodiment of the present invention, also depending on the duration of baking. After baking with different durations, development with the 2-propanol solvent over a period of 40 seconds (step S9 or FIG. 2e) takes place each.

From the curve shape 45, it can be seen that the trench width, and thus the width of the regions in which the negative resist is dissolved out during the development, becomes smaller with increasing duration of baking. The reason for this is that baking contributes to stronger cross-linking of the photoresist. Thereby, the cross-linked or hardened regions in which the negative resist is not dissolved out in developing expand into the non-exposed regions of the negative resist with increasing duration of baking. Hereby, the width of the trenches between the exposed regions in which the negative resist remains in the ensuing developing decreases.

From the curve shape 47, it can be gathered that exposing the negative resist alone is not sufficient for the negative resist in the exposed region to remain on the surface of the material structure. At a duration of zero seconds of baking, the resist thickness after developing is 0 μm. This means that the negative resist on the surface of the material structure has been completely removed also in the exposed region, when baking is not performed.

With increased duration of baking, the cross-linkage of the negative resist in the exposed regions becomes stronger, so that an ever-higher proportion of the negative resist remains on the surface of the material structure after developing. From a duration of 400 seconds on, the resist thickness has then greatly approached a saturation value of 2.2 μm, the thickness of the resist in the conventional method. This asymptotic approach may be explained by the fact that, from a certain duration of baking on, almost the entire exposed resist remains on the surface of the material structure during developing.

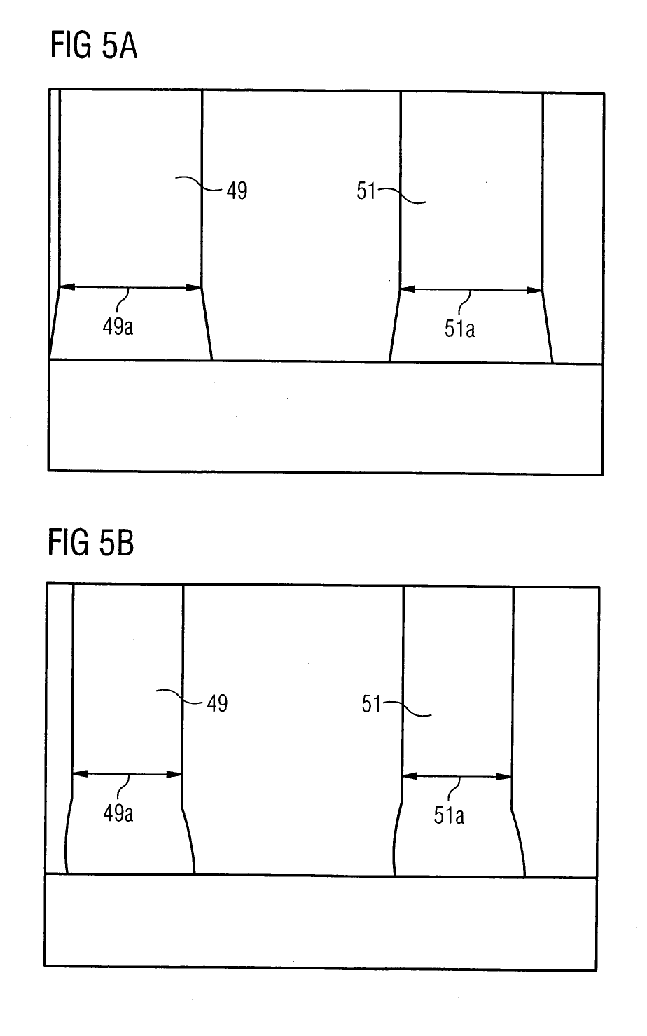

In the following, the influence of the duration of baking on the width of the trenches will be explained in greater detail. FIG. 5a and FIG. 5b show a comparison of trenches forming in the conventional lift-off method in FIG. 5a and in the lift-off method according to an embodiment of the present invention in FIG. 5b. In FIGS. 5a-b, a first trench 49 and a second trench 51 each are illustrated, which have a first trench width 49a and a second trench width 51a.

From FIGS. 5a-b, it can be seen that the first trench and the second trench are characterized by greater widths in the conventional lift-off method than in the lift-off method according to an embodiment of the present invention. The first trench width 49a and the second trench width 51a are about 3 μm in FIG. 3a, whereas the first trench width 41a and the second trench width 51a are about 2.2 μm in FIG. 3b. The reason for the different width of the trenches 49, 51 lies in the fact that in the lift-off method according to an embodiment of the present invention baking has been performed over a longer period, so that the trenches 49, 51 become narrower with increasing duration of baking, as already explained above. While in FIG. 5a baking has been performed over a period of 60 seconds at a temperature of 105° C., baking in FIG. 5b has been performed over a period of 600 seconds at 120° C.

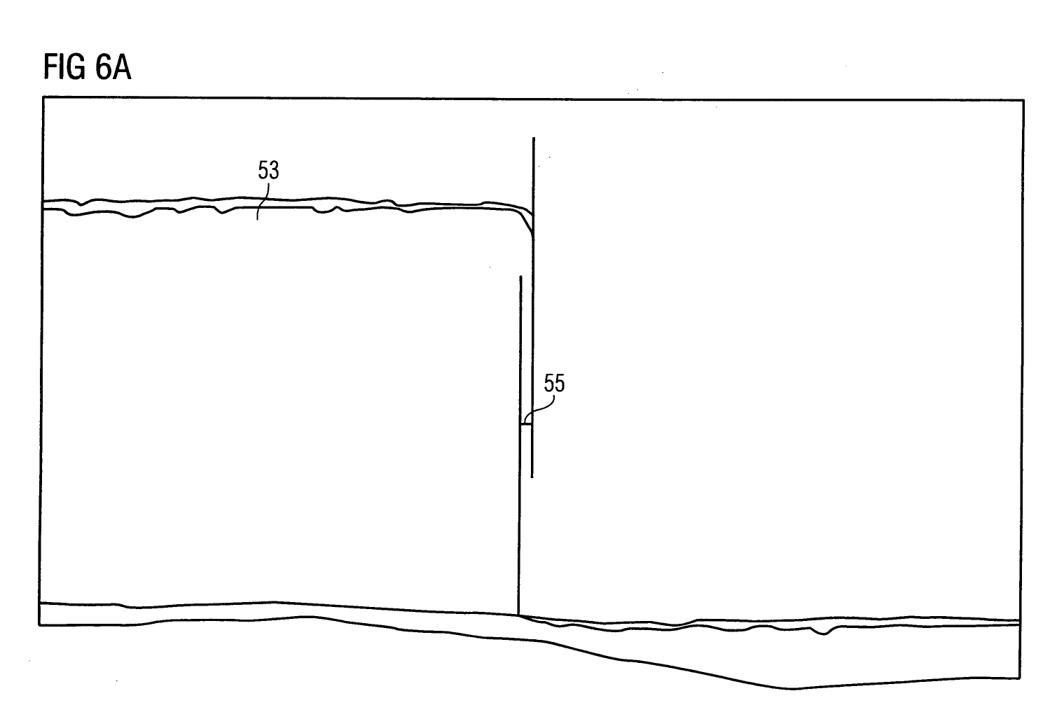

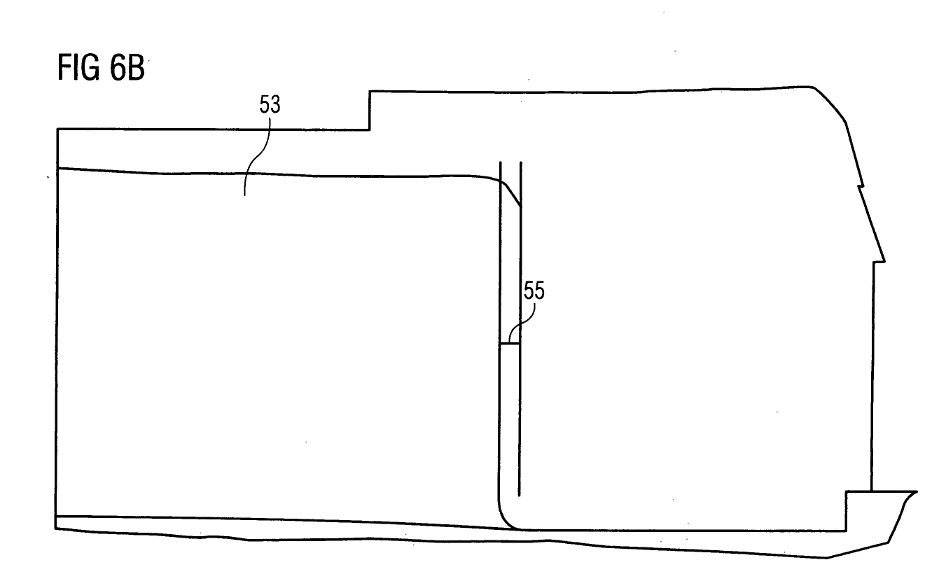

In the following, it will be explained what effects the lift-off method according to an embodiment of the present invention has on flanks of a negative resist region 53. In FIG. 6a, a flank and an overhang 55 in the conventional lift-off method are illustrated, whereas the overhang 55 for the lift-off method according to an embodiment of the present invention is illustrated in FIG. 6b. The negative resist region 53 has been formed according to the conventional lift-off method with baking of a duration of 60 seconds at a temperature of 105° C. in FIG. 6a, whereas the negative resist region 53 has been formed according to an embodiment of the present invention with baking over a duration of 600 seconds and a temperature of 120° C. in FIG. 6b.

The negative resist region 53 illustrated in FIG. 6a and formed with the conventional lift-off method has an overhang 55 of 160 nm, whereas the negative resist region 53 illustrated in FIG. 6b and formed with the lift-off method according to an embodiment of the present invention has an overhang 55 of 300 nm.

From this comparison, it can be seen that the resulting flanks of the negative resist region 53, even after longer baking, have a steepness lying in the order of magnitude of the conventional lift-off method. Thus, the flank steepness of the negative resist region 53 is not significantly reduced by the application of the lift-off method according to an embodiment of the present invention. In the lift-off method according to an embodiment of the present invention and the conventional lift-off method, an undercut or the overhang 55 at the flanks of the negative resist region 53 also lies in the same order of magnitude.

In further examinations, the influence of the duration of baking in the lift-off method according to an embodiment of the present invention on the widths of the trenches has been examined. Here, baking was each performed at a temperature of 120° C., but with three various durations,

a) a duration of 600 seconds;

b) a duration of 900 seconds; and

c) a duration of 1,200 seconds.

Ensuing developing or dissolving out the trenches each took place over a period of 40 seconds in the 2-propanol solvent. The result of these examinations was that the width of the trenches decreases with increasing duration of baking. The reason for this again lies in the fact that the trenches become narrower during baking. The trenches becoming narrower may be compensated by a corresponding lead or a corresponding design of the dimensions of the translucent region and the opaque region of the photomask.

In the above embodiments, the material structure may be embodied as a wafer, a semiconductor die, e.g. a dice or any other form of material structure.

In above embodiments, it is advantageous to perform baking the material structure over a duration ranging from 300 seconds to 1,500 seconds, and preferably ranging from 500 seconds to 600 seconds, but any durations for performing the baking are possible.

In above embodiments, it is advantageous to adjust the temperature present at the material structure to a value ranging from 110° C. to 150° C. during baking, but any temperatures are possible for the process of baking. In above embodiments, baking has been performed in an oven, but any devices in which a correspondingly high temperature can be generated over a corresponding period, such as temperature chambers, are alternatives.

In above embodiments, a 2-propanol solvent was employed for developing the photoresist, but any organic solvents, preferably alcohols, suitable for developing the photoresist, are alternatives, such as PGMEA.

In the above embodiment in FIG. 1, the material structure has been vapor-deposited with gold, titanium or platinum when applying the coating material. Any materials, however, are alternatives hereto.

In the above embodiment, removing the negative resist took place by means of an n-methyl-pyrrolidone solvent. But any solvents capable of removing the photoresist remaining on the material structure are alternatives.

In the above embodiment, in the lift-off method according to an embodiment of the present invention, negative resist was employed as photoresist. But the lift-off method according to an embodiment of the present invention could also be performed with positive resists.

While this invention has been described in terms of several preferred embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

What is claimed is:

1. A lift-off method, comprising the steps of:
providing a material structure;
applying photoresist on a surface of the material structure;
partially exposing the photoresist;
baking the material structure with the partially exposed photoresist applied on the surface of the material structure;
developing the photoresist with an organic, polar developer, such that the photoresist is removed in a first region of the surface, and such that the photoresist remains in a second region of the surface;
applying coating material on the surface of the material structure and the remaining photoresist; and
removing the photoresist, so that the coating material remains only in the first region.

2. The method of claim 1, wherein the organic, polar developer comprises alcohol.

3. The method of claim 1, wherein the organic, polar developer comprises 2-propanol.

4. The method of claim 1, wherein baking the material structure comprises baking the material structure for a duration of between 300 seconds and 1,500 seconds.

5. The method of claim 4, wherein the duration of baking the material structure ranges from 300 seconds to 600 seconds.

6. The method of claim 1, wherein baking the material structure comprises baking the material structure at a temperature of between 110° C. and 150° C.

7. The method of claim 1, wherein the step of removing the photoresist includes a step of bringing the material structure into contact with a solvent comprising n-methyl-pyrrolidone.

8. The method of claim 1, wherein the step of providing the material structure comprises a step of providing a material structure with a metal layer on a surface of the material structure at least partially brought into contact with the organic, polar solvent during developing the photoresist.

9. The method of claim 8, wherein the step of providing the material structure with the metal layer on the surface of the material structure comprises a step of providing the material structure with the metal layer comprising a first metal material and a second metal material different from the first metal material.

10. The method of claim 1, wherein the step of applying coating material on the surface of the material structure includes a step of vapor-depositing the coating material on the surface of the material structure.

11. The method of claim 1, wherein the coating material comprises titanium, gold, or platinum.

12. The method of claim 1, wherein the material structure comprises a wafer.

13. The method of claim 1, wherein the material structure comprises a chip in which a piezoelectric resonator circuit is implemented.

14. The method of claim 13, wherein the piezoelectric resonator is embodied as a bulk acoustic wave resonator.

15. A method, comprising the steps of:
baking a material structure having a surface, the material structure having exposed photoresist disposed on the surface;
developing the photoresist with an organic, polar developer, such that the photoresist is removed in a first region of the surface, and such that the photoresist remains in a second region of the surface;
applying coating material on the surface of the material structure and the remaining photoresist; and
removing the photoresist, so that the coating material remains only in the first region.

16. The method of claim 15, wherein the material structure further comprises a metal layer on a surface of the material structure at least partially brought into contact with the organic, polar solvent during developing the photoresist.

17. The method of claim 16, wherein the metal layer comprises a first metal material and a second metal material different from the first metal material.

18. The method of claim 16, wherein the organic, polar developer comprises alcohol.

19. The method of claim 16, wherein the organic, polar developer comprises 2-propanol.

20. The method of claim 16, wherein baking the material structure comprises baking the material structure at a temperature of between 110° C. and 150° C.
